(19) United States
(12) Patent Application Publication
(10) Pub. No.: US 2010/0123209 A1
(43) Pub. Date: May 20, 2010

(54) Apparatus and Method of Manufacture for Movable Lens on Transparent Substrate

(76) Inventors: Jacques Duparre, Jena (DE); Rickie C. Lake, Meridian, ID (US); Ulrich Boettiger, Boise, ID (US); Shashikant Hegde, Boise, ID (US)

Correspondence Address: DICKSTEIN SHAPIRO LLP, 1825 EYE STREET NW, Washington, DC, 20006-5403, US

(21) Appl. No.: 12/274,256

(22) Filed: Nov. 19, 2008

(51) Int. Cl. H01L 27/00; H01L 21/00

(52) U.S. Cl. 257/432; 438/69; 257/E21.001; 257/E27.001

(57) ABSTRACT

A lens stack having a movable lens attached to a MEMS structure and method of fabricating the same. The method comprises attaching at least one MEMS structure to a transparent substrate. The method further comprises forming a movable lens in contact with the at least one MEMS structure.

### FIELD OF THE INVENTION

Embodiments described herein relate generally to imaging devices incorporating Micro-Electrical-Mechanical Systems (MEMS) technology.

### BACKGROUND OF THE INVENTION

As wireless telephones and cameras decrease in size, there is an increased demand to use smaller lenses for the imaging modules included in these devices. In addition, it is desired that the small lenses retain mobility for operations such as automatic focus. To meet the increased need for smaller lenses with retained mobility, MEMS technology has been incorporated into lens stacks.

The process of manufacturing lens stacks incorporating MEMS technology is, however, expensive because the MEMS structures and lenses are created in separate processes, and then the two are combined in a subsequent process. In addition, the lens stacks use silicon or light inhibiting substrates between lenses that require the creation of an opening to allow for the full transfer of light through the lens stack. Such an opening, however, may be highly reflective and may cause undesirable stray light rays.

What is needed is an imaging module and method of manufacturing the module that directly replicates the lens onto a MEMS structure with a transparent substrate in the optical path.

### BRIEF DESCRIPTION OF THE DRAWINGS

FIG. 1A shows a lens stack according to an embodiment described herein.

FIG. 1B shows a lens stack according to an embodiment described herein.

FIG. 1C shows a top-down view of a lens stack according to an embodiment described herein.

FIG. 2A shows a portion of a lens stack at an initial stage of processing according to an embodiment described herein.

FIG. 2B shows a portion of a lens stack at a stage of processing subsequent to that shown in FIG. 2A.

FIG. 2C shows a portion of a lens stack at a stage of processing subsequent to that shown in FIG. 2B.

FIG. 2D shows a portion of a lens stack at a stage of processing subsequent to that shown in FIG. 2C.

FIG. 2E shows a portion of a lens stack at a stage of processing subsequent to that shown in FIG. 2D.

FIG. 3A shows a portion of a lens stack at an initial stage of processing according to an embodiment described herein.

FIG. 3B shows a portion of a lens stack at a stage of processing subsequent to that shown in FIG. 3A.

FIG. 3C shows a portion of a lens stack at a stage of processing subsequent to that shown in FIG. 3B.

FIG. 3D shows a portion of a lens stack at a stage of processing subsequent to that shown in FIG. 3C.

FIG. 3E shows a portion of a lens stack at a stage of processing subsequent to that shown in FIG. 3D.

FIG. 4A shows a portion of a lens stack at a stage of processing subsequent to that shown in FIG. 3A.

FIG. 4B shows a portion of a lens stack at a stage of processing subsequent to that shown in FIG. 4A.

FIG. 4C shows a portion of a lens stack at a stage of processing subsequent to that shown in FIG. 4B.

FIG. 5A shows a portion of a lens stack at a stage of processing subsequent to that shown in FIG. 3A.

FIG. 5B shows a portion of a lens stack at a stage of processing subsequent to that shown in FIG. 5A.

FIG. 5C shows a portion of a lens stack at a stage of processing subsequent to that shown in FIG. 5B.

FIG. 6A shows a portion of a lens stack at a stage of processing subsequent to that shown in FIG. 3A.

FIG. 6B shows a portion of a lens stack at a stage of processing subsequent to that shown in FIG. 6A.

FIG. 6C shows a portion of a lens stack at a stage of processing subsequent to that shown in FIG. 6B.

FIG. 6D shows a portion of a lens stack at a stage of processing subsequent to that shown in FIG. 6C.

FIG. 7A shows a portion of a lens stack at an initial stage of processing according to an embodiment described herein.

FIG. 7B shows a portion of a lens stack at a stage of processing subsequent to that shown in FIG. 7A.

FIG. 7C shows a portion of a lens stack at a stage of processing subsequent to that shown in FIG. 7B.

FIG. 7D shows a portion of a lens stack at a stage of processing subsequent to that shown in FIG. 7C.

FIG. 8A shows a portion of a lens stack at an initial stage of processing according to an embodiment described herein.

FIG. 8B shows a portion of a lens stack at a stage of processing subsequent to that shown in FIG. 8A.

FIG. 8C shows a portion of a lens stack at a stage of processing subsequent to that shown in FIG. 8B.

FIG. 8D shows a portion of a lens stack at a stage of processing subsequent to that shown in FIG. 8C.

FIG. 8E shows a portion of a lens stack at a stage of processing subsequent to that shown in FIG. 8D.

FIG. 9 shows a lens stack according to an embodiment described herein.

FIG. 10 shows an imaging module according to an embodiment described herein.

FIG. 11 shows digital camera according to an embodiment described herein.

### DETAILED DESCRIPTION OF THE INVENTION

In the following detailed description, reference is made to various embodiments that are described with sufficient detail to enable those skilled in the art to practice them. It is to be understood that other embodiments may be employed, and that various structural or logical changes may be made.

Embodiments described herein related to lens stacks and methods of their manufacture. In desired embodiments, the lens stacks use only transparent substrates, therefore alleviating stray light issues found in the prior art that created openings in substrates. Embodiments described herein relate to lens stacks incorporating MEMS technology that contain only glass substrates, allowing for better coefficient of thermal expansion (CTE) matching than lens stacks with at least one silicon substrate. In addition, in desired embodiments, the lens stacks are manufactured by imprinting the movable lenses directly on the MEMS structures, avoiding additional manufacturing processes. Figures described herein show one structure of many that may be simultaneously formed at a wafer level.

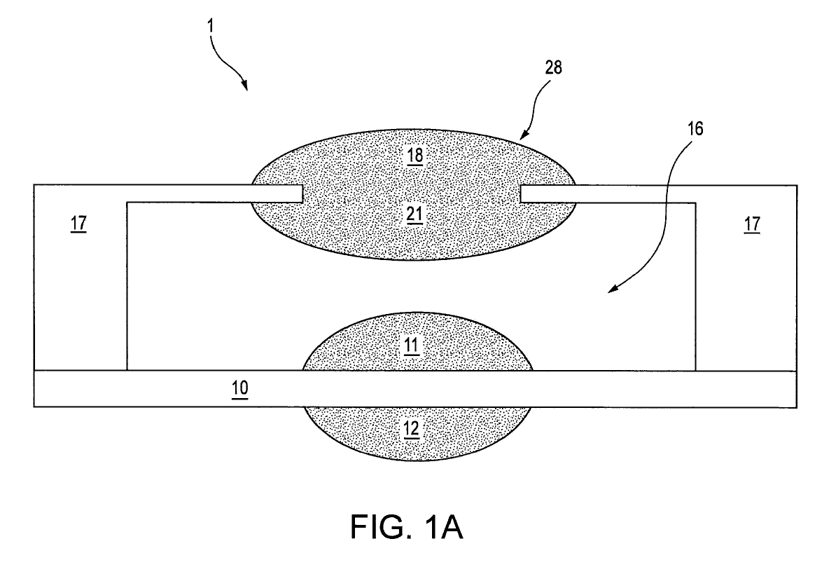

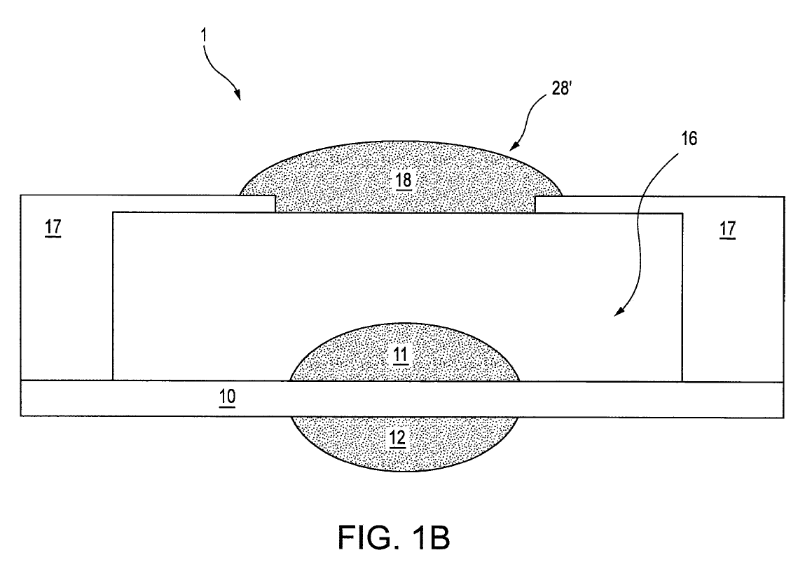

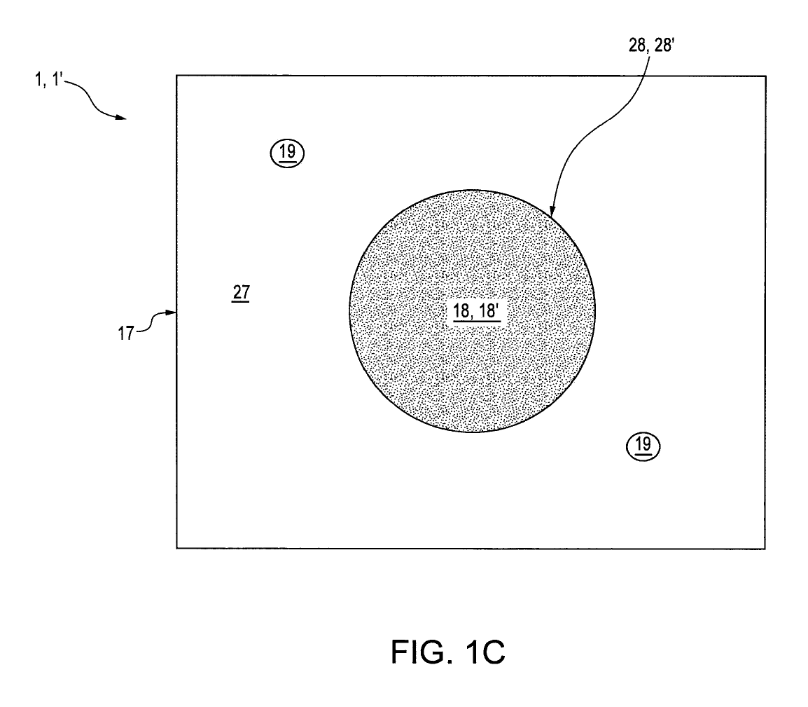

Now referring to the figures, where like reference numbers designate like elements, FIGS. 1A and 1B show lens stacks 1 and 1′, respectively, according to embodiments described herein. Lens stack 1 has a movable lens structure 28 having two lenses 18, 21 and lens stack 1′ has a movable lens structure 28′ having one lens 18.

Referring to FIG. 1A, lens stack 1 contains movable lens structure 28 comprising two opposing lenses 18, 21. MEMS structures 17 support lens structure 28, and are attached to transparent substrate 10. Transparent substrate 10 may have two opposing lenses 11, 12 formed therein, may only have one of the lenses 11, 12, or may have no lenses at all. Cavity 16 separates lens 21 from lens 11 (or from the transparent substrate 10 if lens 11 is not present).

Referring to FIG. 1B, lens stack 1′ contains movable lens structure 28′ comprising lens 18. MEMS structures 17 support lens structure 28′, and are attached to transparent substrate 10. Transparent substrate 10 may have two opposing lenses 11, 12 formed therein, may only have one of the lenses 11, 12, or may have no lenses at all. Cavity 16 separates lens 21 from lens 11 (or from the transparent substrate 10 if lens 11 is not present).

The MEMS structures 17 shown in FIGS. 1A and 1B (and all subsequent figures) may be, e.g., piezoelectiric, electrostatic or magnetostatic, and may incorporate, e.g, hinges (not shown) or actuators (not shown). The MEMS structures 17 shown in FIGS. 1A and 1B (and all subsequent figures) are intended to be representative of any appropriate MEMS implementation and are, therefore, not intended to be limiting. In addition, the sizes and shapes of lenses 11, 12, 18 and 21 shown in FIGS. 1A, 1B and all subsequent figures are only intended to be representative, and lens of any size and shape may be formed in any of the methods of manufacturing the lens structures shown in FIGS. 1A and 1B.

While convex lenses are shown in FIGS. 1A and 1B, concave or partially concave lenses may be used for any or all of the lenses 11, 12, 18, 21. Each of the lenses may be comprised of a rigid material (e.g., an Ormocer® such as Ormocore® or Ormocomp®, manufactured by Microresist Technology GmbH, Berlin, Germany) or a flexible material (e.g., polydimethylsiloxane (PDMS)). When lenses 18 and 21 are comprised of a rigid material, they will be restricted to axial or lateral movement. When lenses 18 and 21 are comprised of a flexible material, other properties of the lenses may also change (e.g., shape, radius of curvature) by stretching or otherwise distorting the lenses. In addition, lens material can vary along the lens radius by, e.g., strong electromagnetic or particle radiation during fabrication, to influence the mechanical properties of the lens. The transparent substrate 10 may be comprised of a glass (e.g., Borofloat® 33 manufactured by Schott AG, Germany).

FIG. 1C shows a top-down view of a lens stack 1, V. Lens structure 28, 28′ may be centered in MEMS structures 17. The top 27 of MEMS structures 17 may be solid, except for the opening that exposes lens 18, 18′. MEMS structures 17 may have small holes 19 through which is dissolved sacrificial material in embodiments described herein.

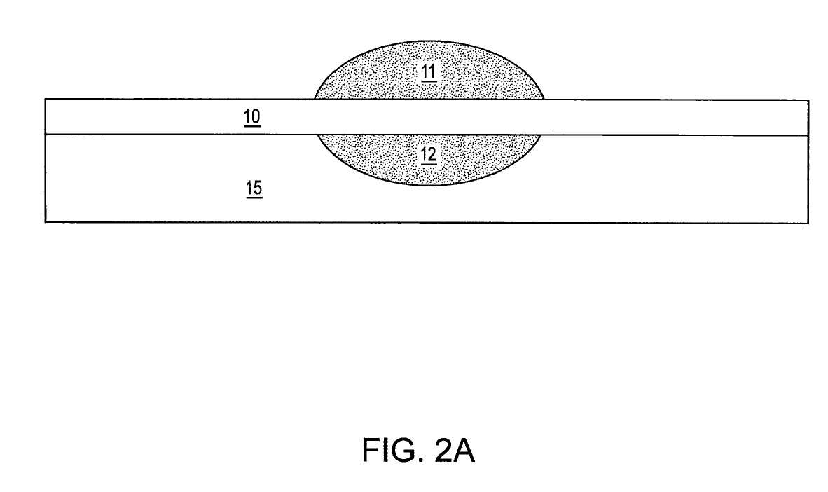

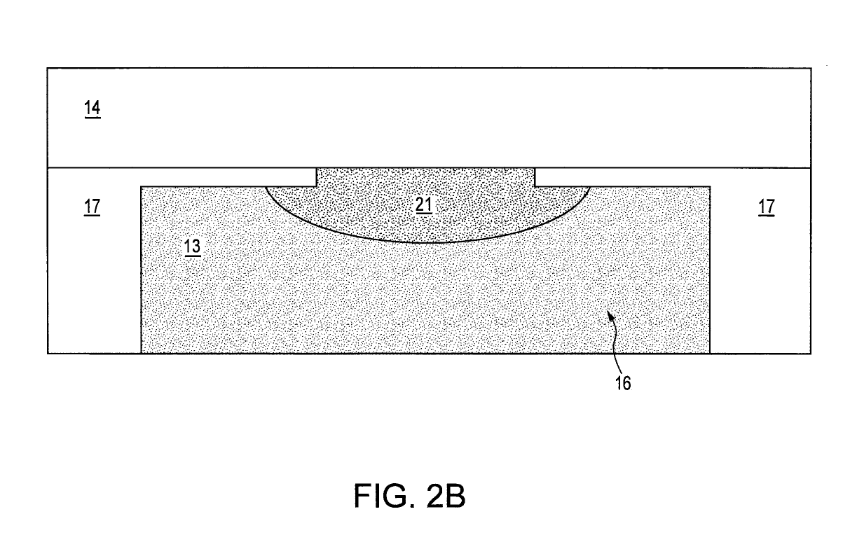

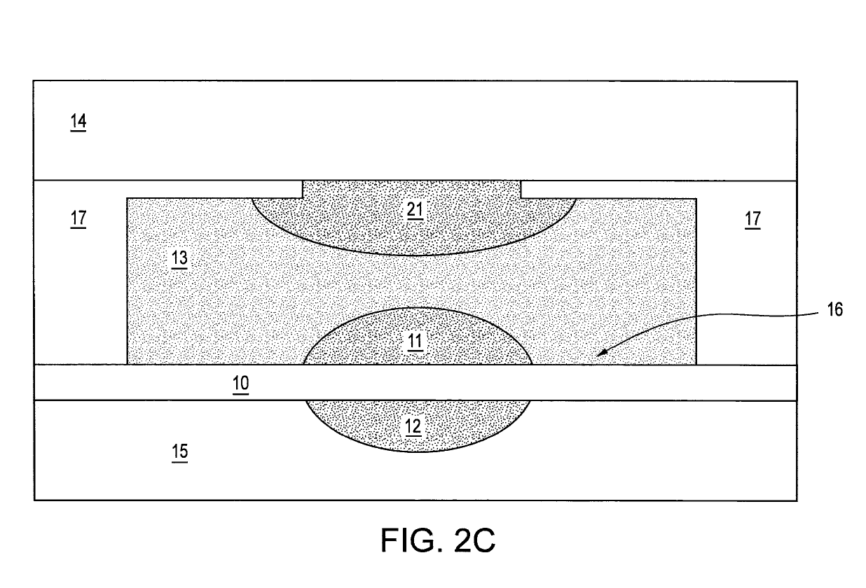

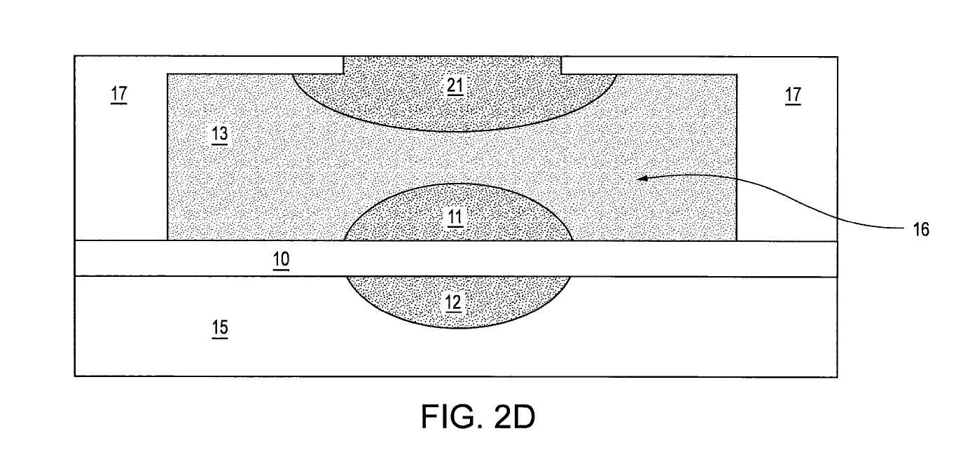

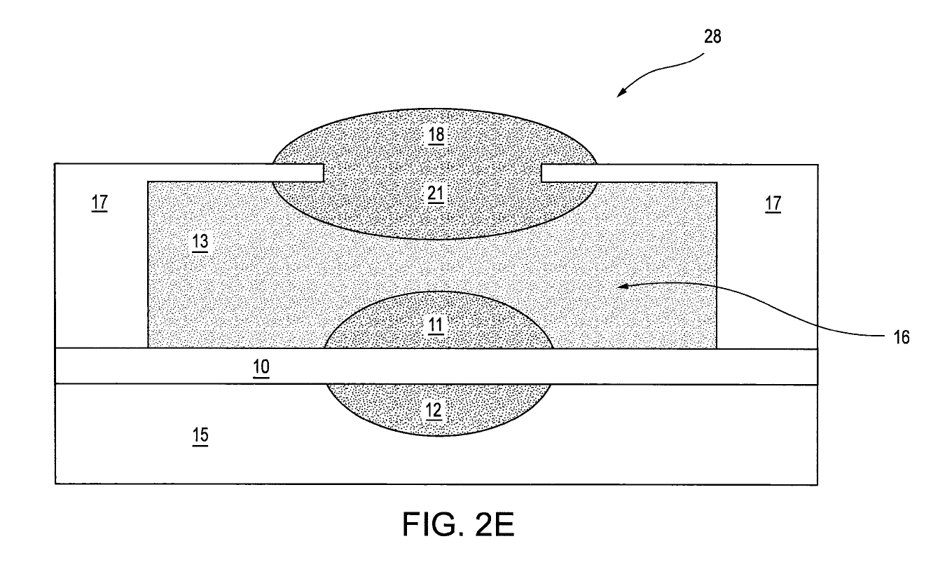

FIGS. 2A-2E show a first example of a method of manufacturing lens stack 1 shown in FIG. 1A. Referring to FIG. 2A, the first step is to create lenses 11, 12 on opposite sides of transparent substrate 10. Alternatively, only one lens 11 or 12 is formed on transparent substrate 10, or no lenses are formed on transparent substrate 10. The lenses 11, 12 may be formed by any suitable method, e.g., lens replication. A temporary carrier 15 is attached to one side of the transparent substrate 10. The temporary carrier 15 may be comprised of, for example, silicon, polymer, glass or polymer-on-glass. In addition, the temporary carrier 15 need not support the entire surface of transparent substrate 10.

Referring to FIG. 2B, in a step separate from that described in FIG. 2A, MEMS structures 17 are created on silicon carrier 14 by any suitable method, e.g., surface micromachining, such that a cavity 16 is formed. Lens 21 is imprinted on the MEMS structures 17 inside the cavity 16 by any suitable method, e.g., ultraviolet lens replication. The cavity 16 is then at least partially filled with sacrificial material 13. The sacrificial material 13 may be, for example, SiO₂ or a polymer, and may be deposited in the cavity by any suitable method, e.g., vapor deposition, sputtering, dispensing or spin-coating.

Referring to FIG. 2C, MEMS structures 17 are then attached to transparent substrate 10 by any suitable method. Referring to FIG. 2D, the silicon carrier 14 is etched away to reveal lens 21. Referring to FIG. 2E, lens 18 is imprinted over lens 21 and MEMS structures 17 by any suitable method, e.g., lens replication, to produce movable lens structure 28.

The sacrificial material 13 (FIGS. 2B-2E) is then removed by any available method, e.g., by being dissolved through small holes 19 (FIG. 1C) in the MEMS structures 17, and the temporary carrier 15 (FIGS. 2A, 2C-2E) is removed to produce the lens stack 1 illustrated in FIG. 1A.

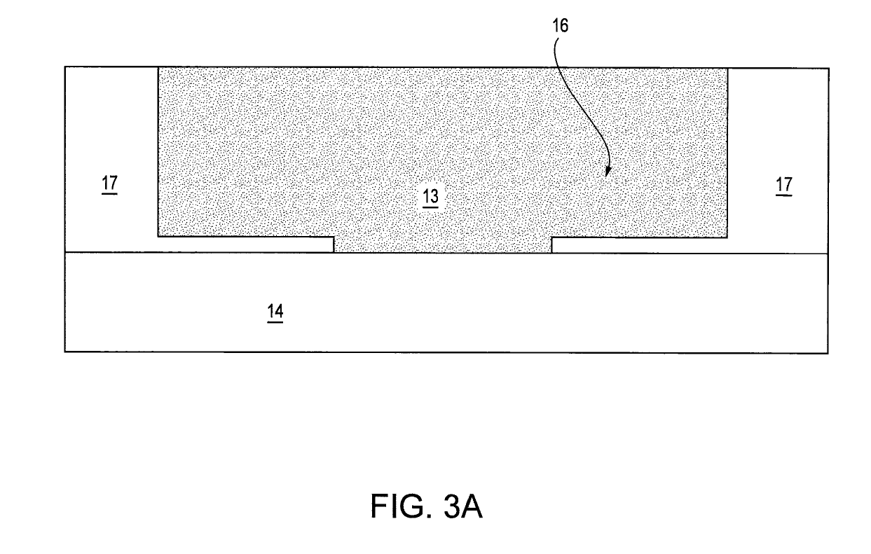

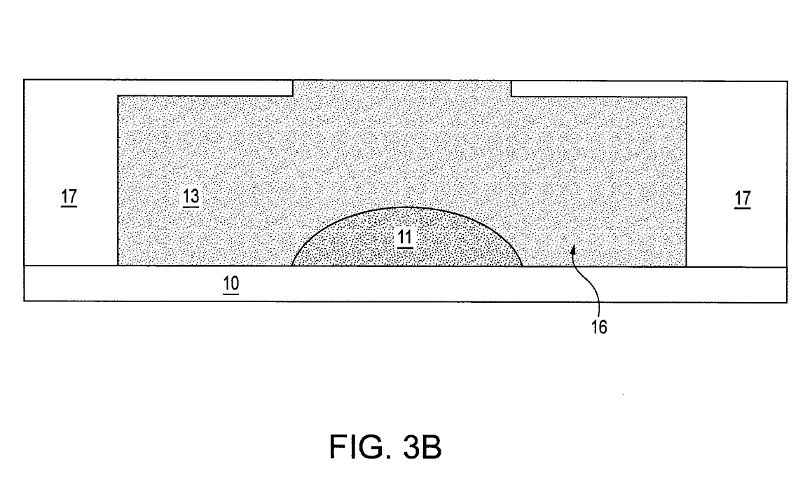

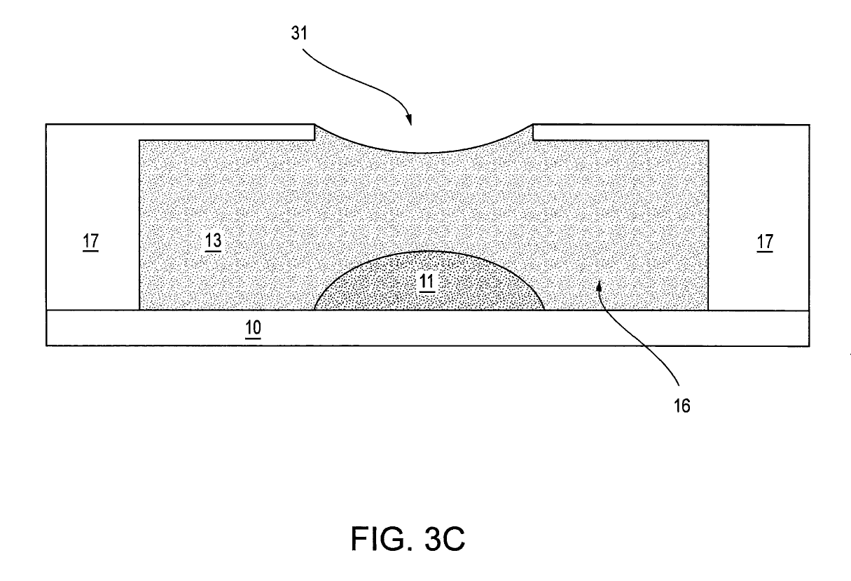

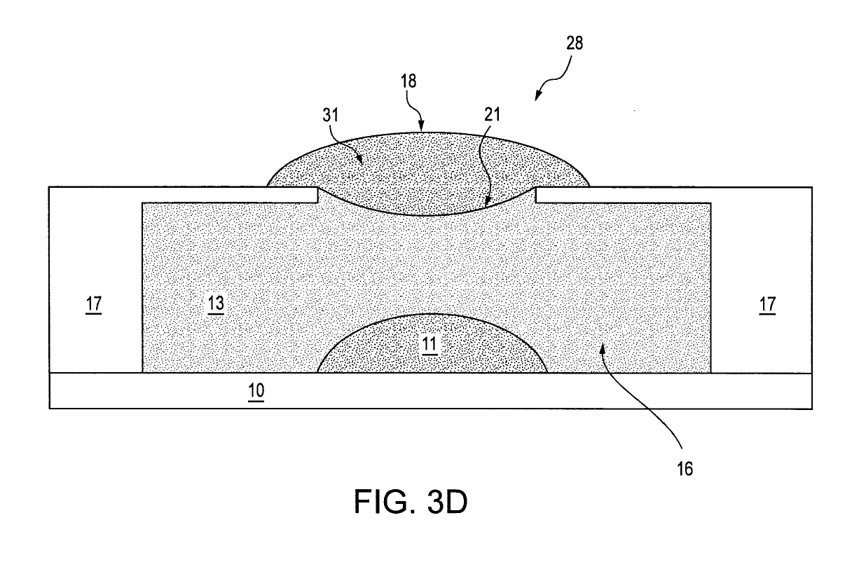

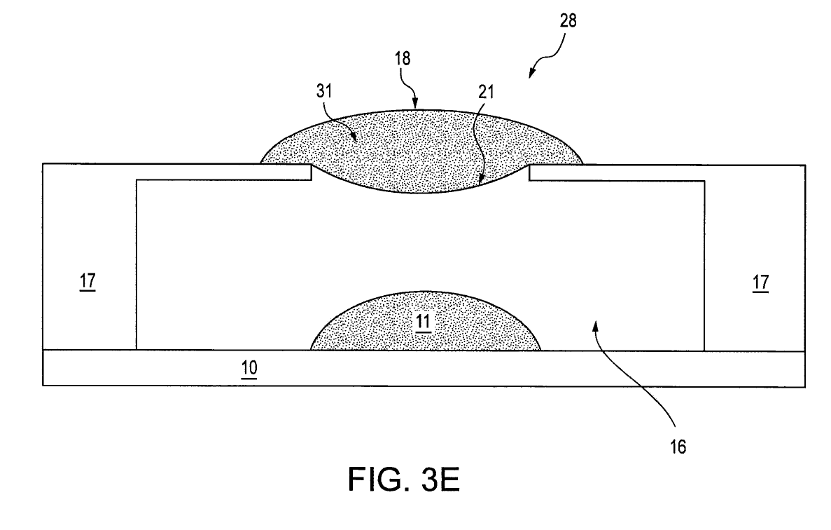

FIGS. 3A-3E show a second example of a method of manufacturing a lens stack 1 shown in FIG. 1A. Referring to FIG. 3A, the first step is to create MEMS structures 17 over silicon carrier 14 by any suitable method, e.g., surface micromachining. A cavity 16 is formed in the process and is filled with a sacrificial material 13, e.g., SiO₂.

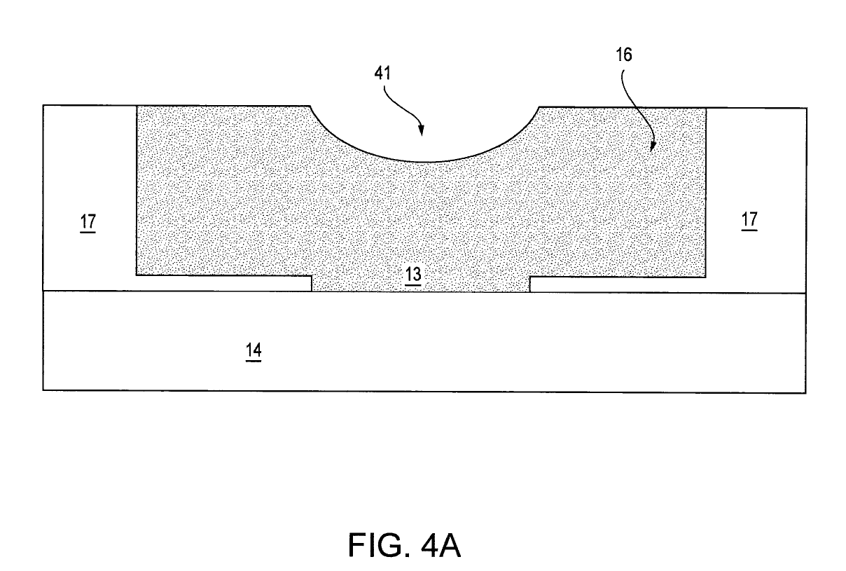

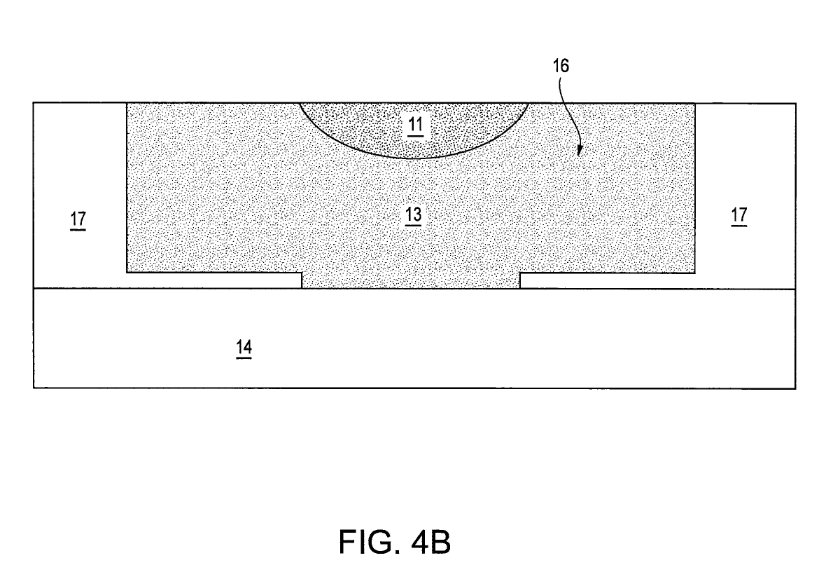

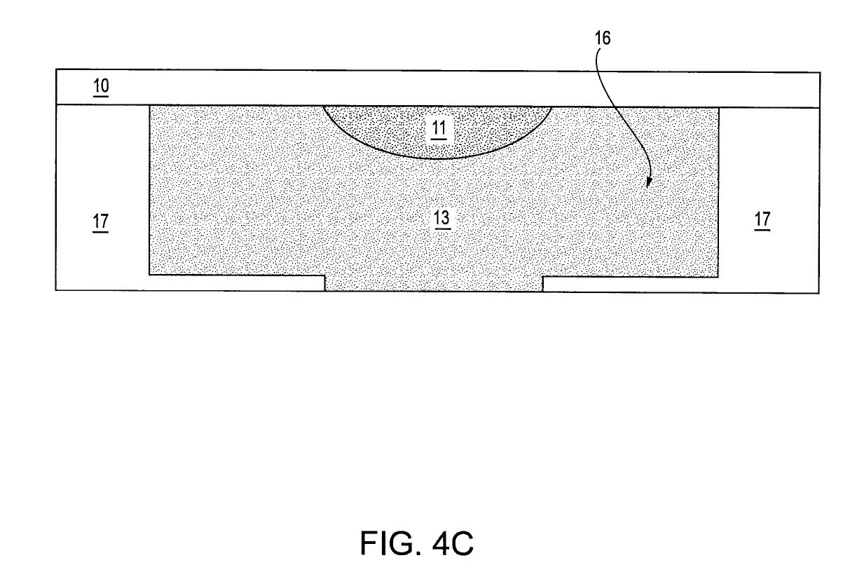

Referring to FIG. 3B, the MEMS structures 17 and sacrificial material 13 are transferred from the silicon carrier 14 (FIG. 3A) to a transparent substrate 10 optionally having a lens 11 formed thereon. The transfer occurring in FIG. 3B is discussed below and shown in greater detail in FIGS. 4A-6D. While the embodiment shown in FIGS. 3A-3E shows a transparent substrate 10 having a lens 11, transparent substrate 10 need not have a lens 11. If lens 11 is not present on transparent substrate 10, the transfer shown in FIG. 3B can occur without the additional steps shown in FIGS. 4A-6D. Referring to FIG. 3C, a cavity 31 is formed in the sacrificial material 13 by any suitable method, e.g., etching or imprinting.

Referring to FIG. 3D, lens structure 28 is replicated over the cavity 31, creating lenses 18 and 21. Prior to lens replication, cavity 31 may be coated with a thin polymer, e.g., an Ormocer® such as Ormocore® or Ormocomp®, manufactured by Microresist Technology GmbH, Berlin, Germany, as described in U.S. patent application Ser. No. ______, entitled Over-Molded Glass Lenses and Method of Forming the Same, filed Jul. 1, 2008 and assigned to Micron Technology, Inc, which is incorporated herein by reference.

In a first alternative embodiment, the sacrificial material 13 is a material that can be imprinted by hot embossing, e.g., polycarbonate. In a second alternative embodiment, the sacrificial layer 13 is removed and replaced with an ultraviolet-curing sacrificial layer, e.g., a polymer, that can be imprinted by a standard ultraviolet embossing process.

Referring to FIG. 3E, the sacrificial material 13 is removed by any available technique such as, e.g., by being dissolved through small holes 19 (FIG. 1C) in the MEMS structures 17. A lens 12 (FIG. 1A) may be imprinted on the bottom of transparent substrate 10 by any suitable method, e.g., lens replication, to produce the finished lens stack 1 shown in FIG. 1A.

FIGS. 4A-4C show a first example of a method for transferring MEMS structures 17 from a silicon carrier 14 to a transparent substrate 10 having a lens 11, as discussed above for the example shown in FIG. 3B. Referring to FIG. 4A, a cavity 41 is created in the sacrificial material 13 by any suitable method, e.g., etching or imprinting. Referring to FIG. 4B, the cavity 41 is filled with a lens replication material, e.g., a ultraviolet-curable polymer, to create lens 11. The lens 11 is then planarized. Referring to FIG. 4C, the transparent substrate 10 is attached to lens 11 and MEMS structures 17 and carrier 14 is removed.

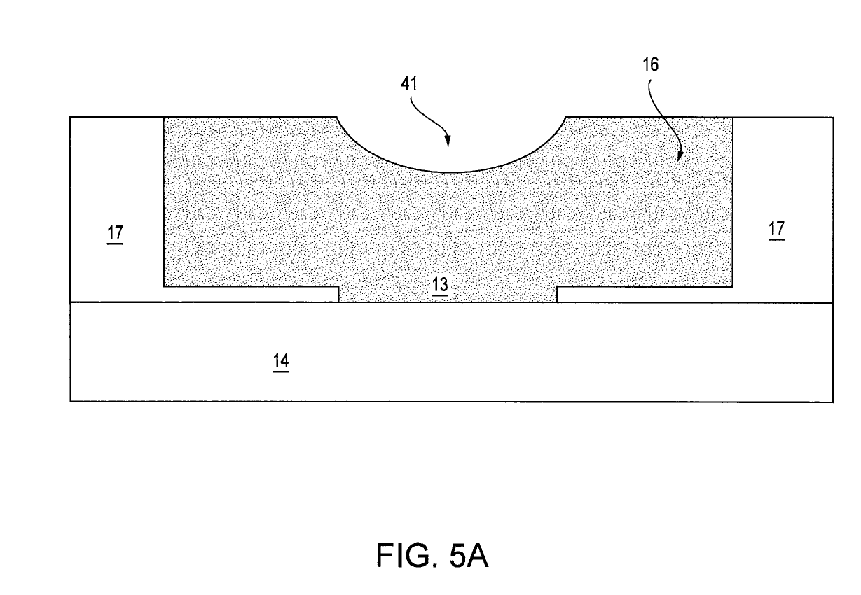

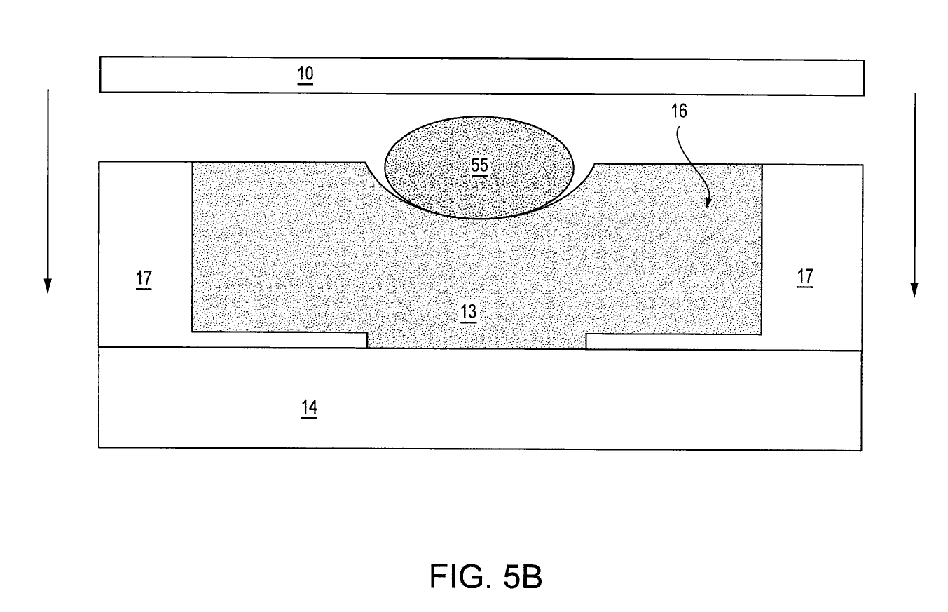

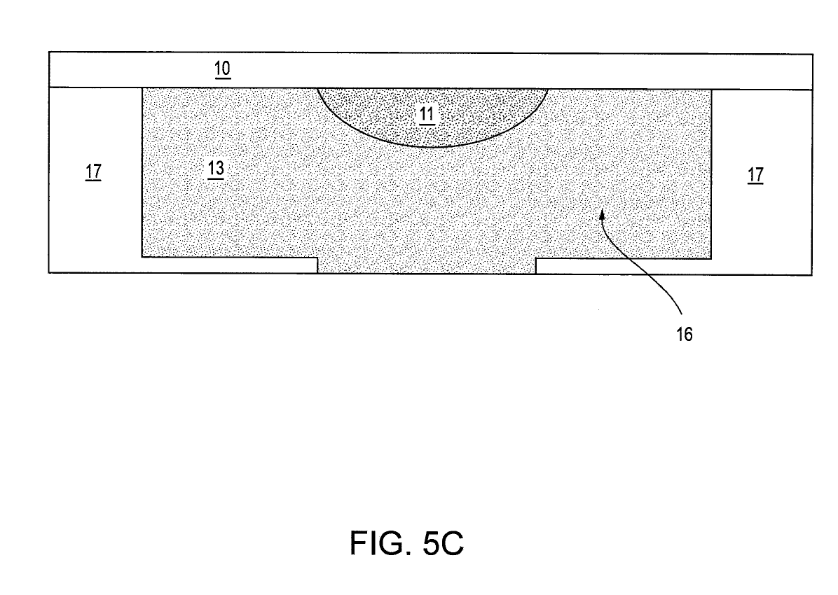

FIGS. 5A-5C show a second example of a method for transferring MEMS structures 17 from a silicon carrier 14 to a transparent substrate 10 having a lens 11, as discussed for the example shown in FIG. 3B. Referring to FIG. 5A, a cavity 41 is created in the sacrificial material 13 by any suitable method, e.g., etching. Referring to FIG. 5B, the cavity 41 is filled with a lens replication material 55, e.g., a ultraviolet-curable polymer, and transparent substrate 10 is attached to MEMS structures 17 such that the lens replication material 55 is compressed into the cavity 41 to create lens 11 (FIG. 5C). Referring to FIG. 5C, the silicon carrier 14 is then removed.

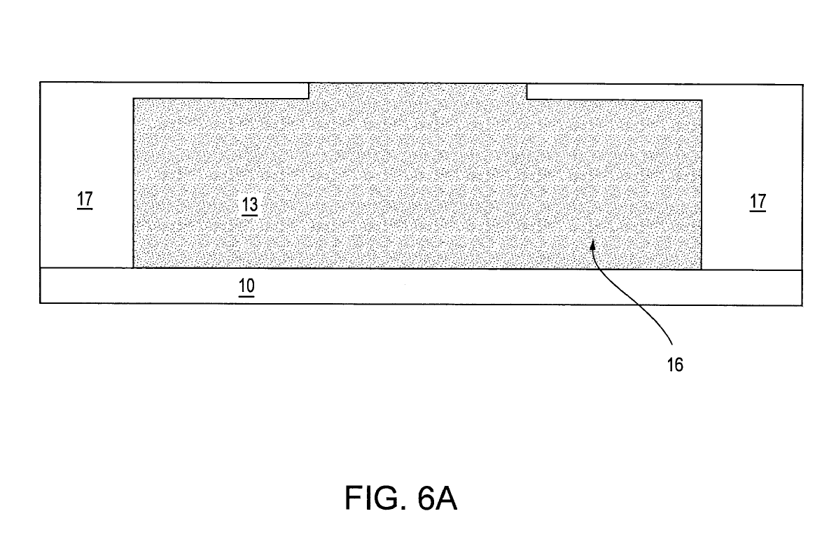

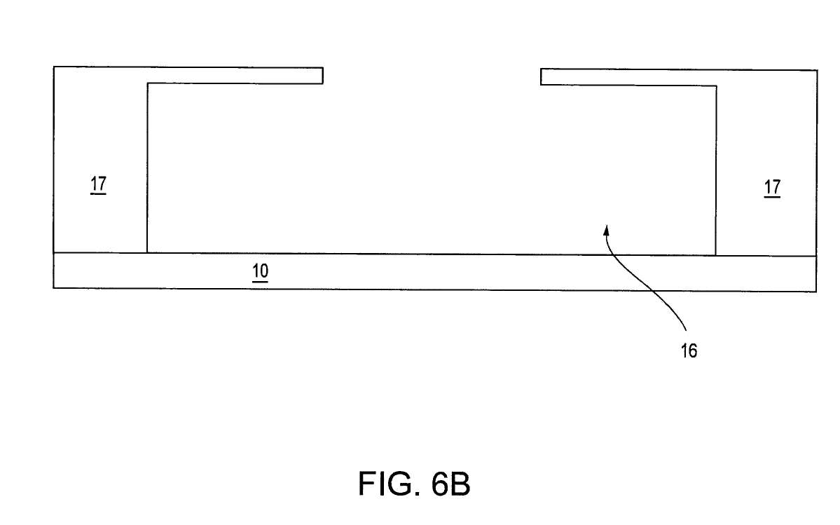

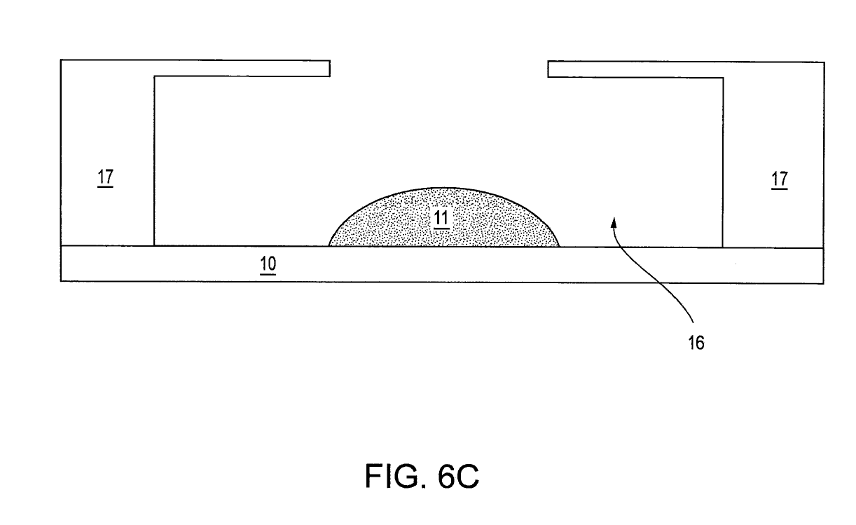

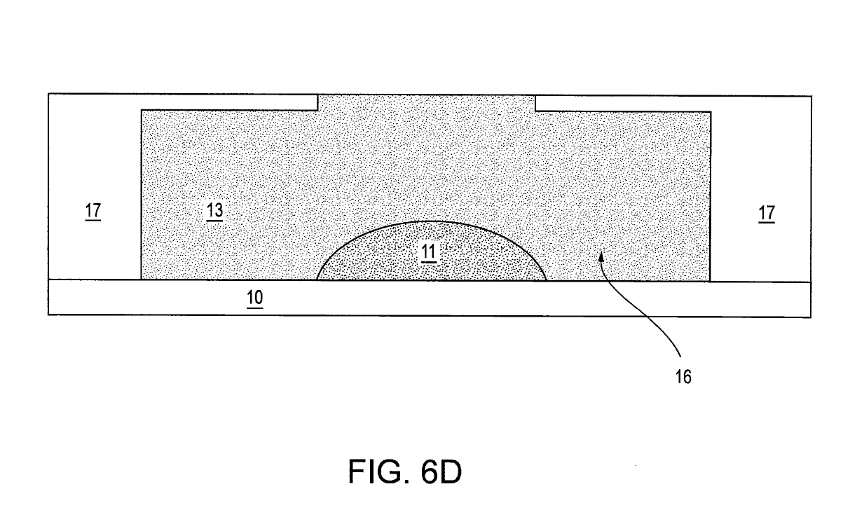

FIGS. 6A-6D show a third example of a method for transferring MEMS structures 17 from a silicon carrier 14 to a transparent substrate 10 having a lens 11, as discussed for the example shown in FIG. 3B. Referring to FIG. 6A, the MEMS structures 17 are attached to a transparent substrate 10 and removed from the silicon carrier 14 (FIG. 3B). Referring to FIG. 6B, the sacrificial material 13 is removed by any available method, e.g., by being dissolved through small holes 19 (FIG. 1C) in the MEMS structures 17. Referring to FIG. 6C, the lens 11 is imprinted on the transparent substrate 10 by any suitable method, e.g., ultraviolet lens replication. Referring to FIG. 6D, the cavity 16 is filled with sacrificial material 13 and planarized.

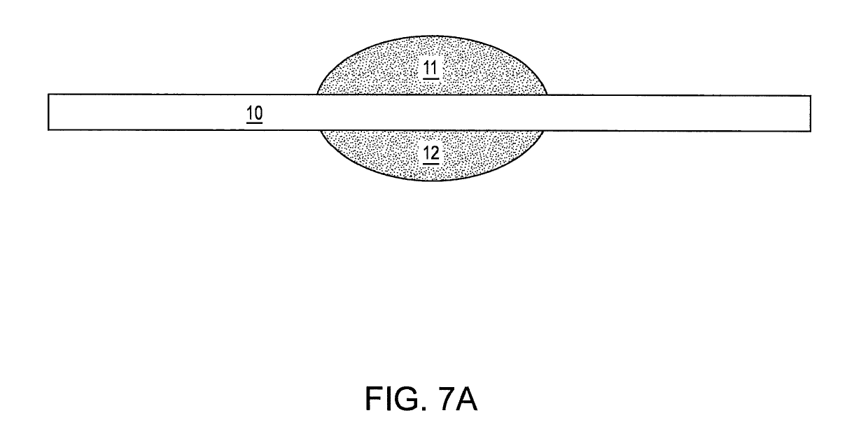

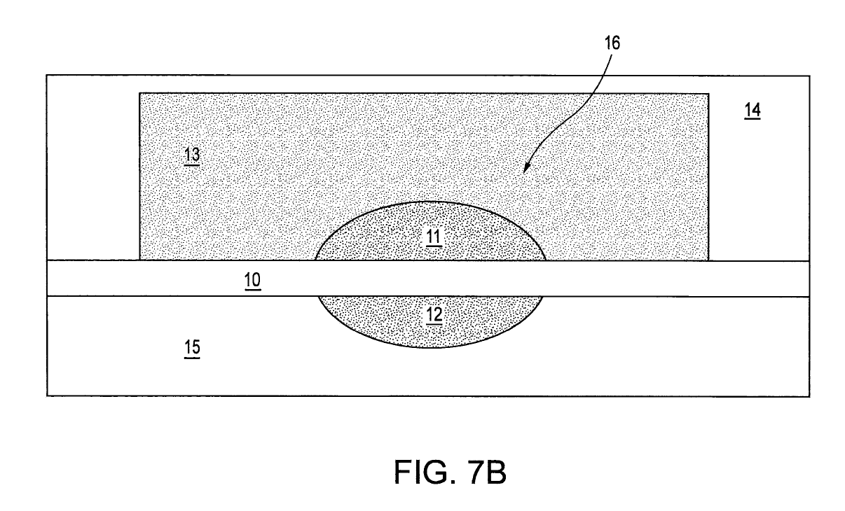

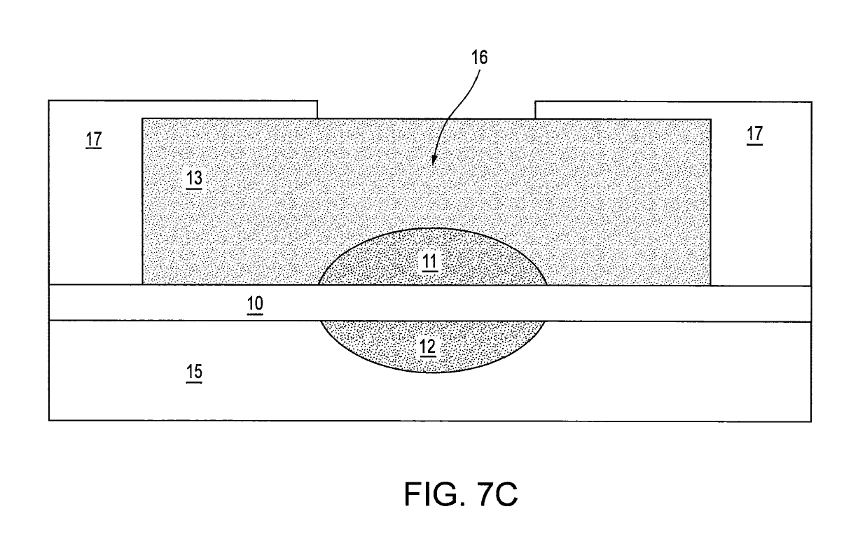

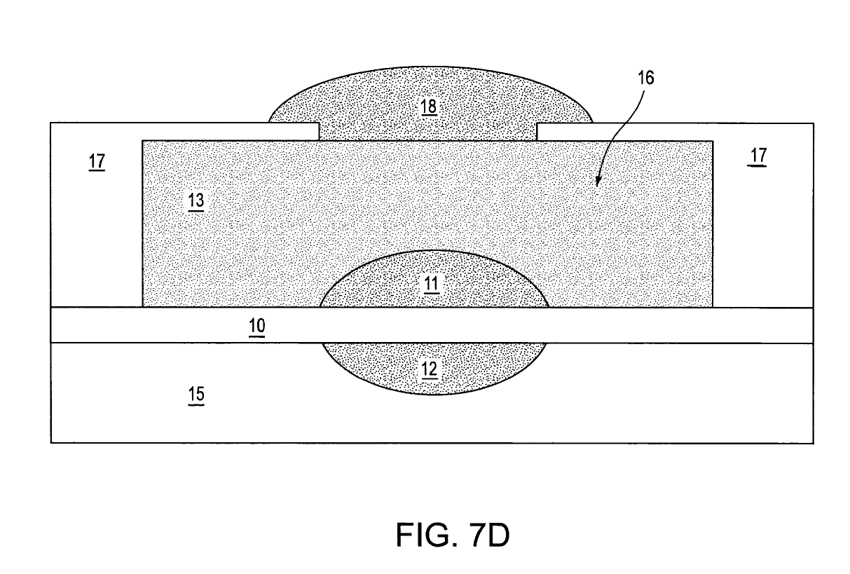

FIGS. 7A-7D show a first example of a method of manufacturing a lens stack 1′ shown in FIG. 1B. Referring to FIG. 7A, the first step is to create lenses 11, 12 on opposite sides of the transparent substrate 10. Alternatively, only one lens 11 or 12 is formed on transparent substrate 10, or no lenses are formed on transparent substrate 10. The lenses 11, 12 may be formed by any suitable method, e.g., ultraviolet lens replication.

Referring to FIG. 7B, a temporary carrier 15 is attached to one side of the transparent substrate 10. The temporary carrier 15 may be comprised of, for example, silicon, polymer, glass or polymer-on-glass. A silicon carrier 14 is attached to the other side of the transparent substrate 10. The silicon carrier 14 has a cavity 16 at least partially filled with sacrificial material 13. The cavity may be created by any suitable method, e.g., etching. The sacrificial material 13 may be, for example, SiO₂, and may be deposited in the cavity by any suitable method, e.g., vapor deposition, sputtering, dispensing or spin-coating.

Referring to FIG. 7C, silicon surface micromachining is performed on silicon carrier 14 (FIG. 7B) to form the MEMS structures 17. Referring to FIG. 7D, lens 18 is created over the MEMS structures 17 and sacrificial material 13. In a preferred embodiment, the lens 18 is imprinted in an ultraviolet lens replication material. To create the finished lens stack 1′ shown in FIG. 7B, the sacrificial material 13 is removed by any available method, e.g., by being dissolved through small holes 19 (FIG. 1 C) in the MEMS structures 17. In addition, the temporary carrier 15 (FIGS. 7A-7D) is removed.

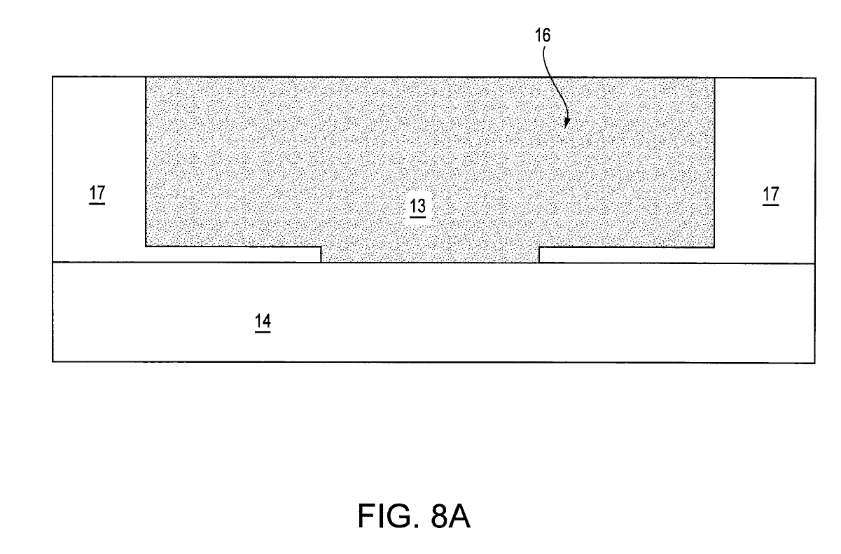

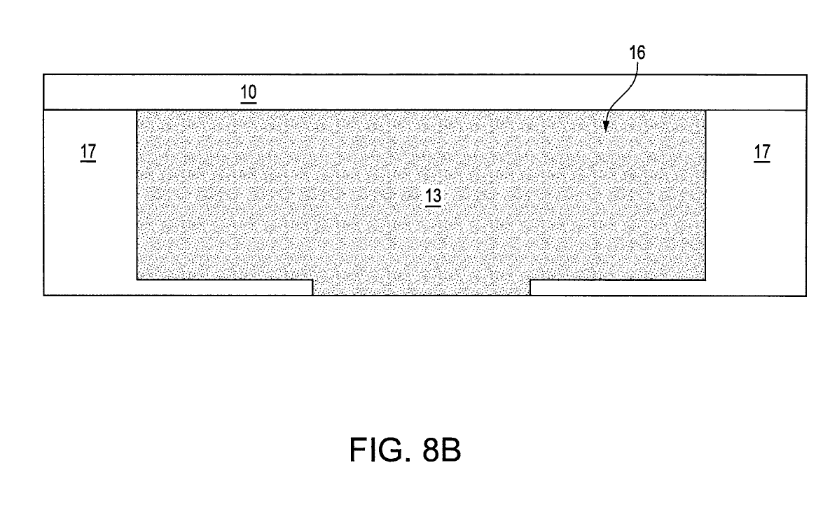

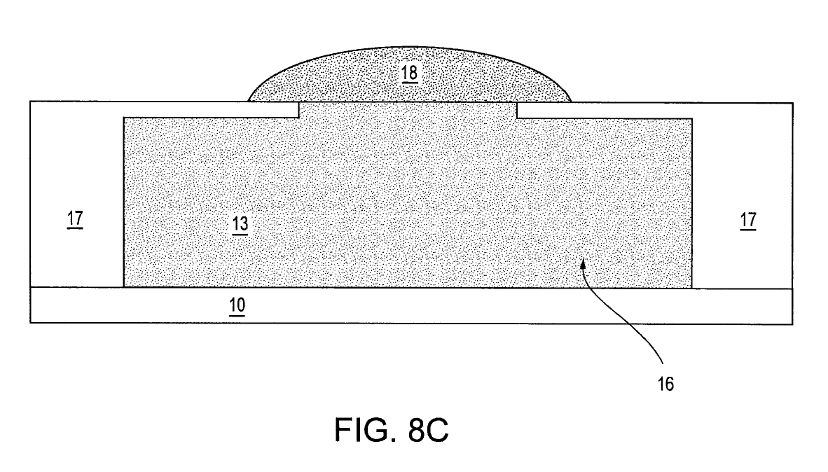

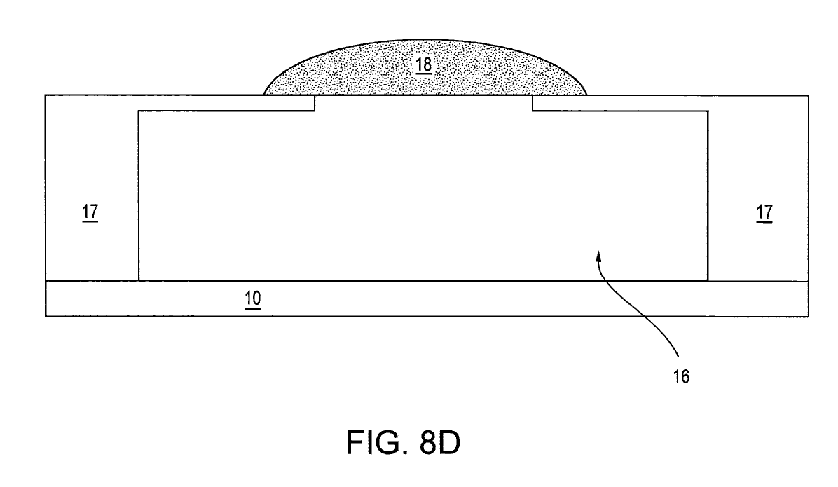

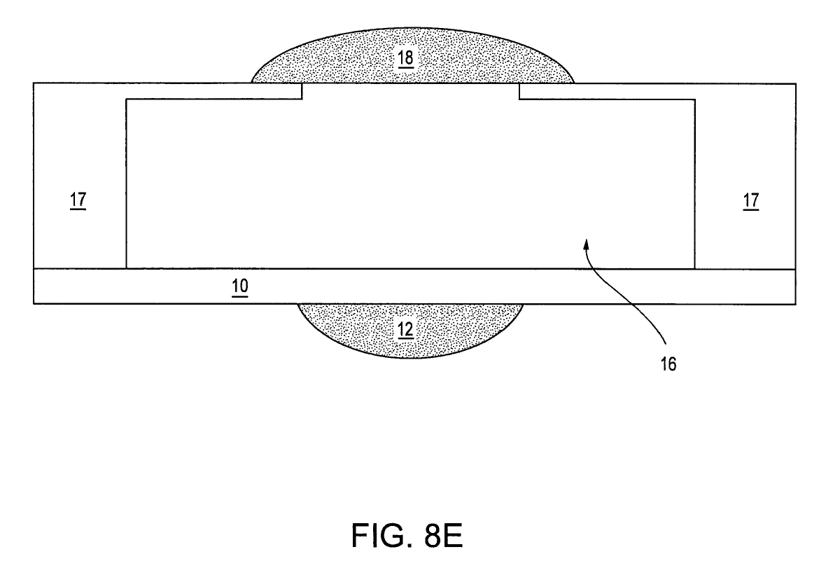

FIGS. 8A-8E show a second example of a method of manufacturing a lens stack 1′ shown in FIG. 1B. Referring to FIG. 8A, the first step is to create MEMS structures 17 over silicon carrier 14 by any suitable method, e.g., surface micromachining. Cavity 16 is formed therein and is filled with a sacrificial material 13, e.g., SiO₂.

Referring to FIG. 8B, transparent substrate 10 is attached to the top of the MEMS structures 17 and the silicon carrier 14 is removed by, e.g., etching. While the embodiment shown in FIG. 8B does not have a lens 11 on the transparent substrate 10, a lens 11 may be present as in the embodiment shown in FIGS. 3A-3E. If lens 11 is present, additional steps, e.g., those shown in FIGS. 4A-6D, must be taken to allow for transfer to the transparent substrate 10.

Referring to FIG. 8C, a lens 18 is replicated over the MEMS structures 17 and sacrificial material 13. Referring to FIG. 8D, the sacrificial material 13 is removed by any available method, e.g., by being dissolved through small holes 19 (FIG. 1C) in the MEMS structures 17. Referring to FIG. 8E, a lens 12 may be imprinted on the exposed side of transparent substrate 10 to produce the lens stack 1′ shown in FIG. 1B without optional lens 11. It should be noted that lens 12 is also optional.

In the method embodiments described in FIGS. 2A-8E, it is important that the lens replication material used to create lens 18 does not contact any of the movable parts of joints of the MEMS structures 17, to avoid obstructing the movement of the MEMS structures 17. This can be achieved by a relative replication as described in U.S. patent application Ser. No. ______, entitled Stamp with Mask Pattern for Discrete Lens Replication, filed on ______ and assigned to Micron Technology, Inc.

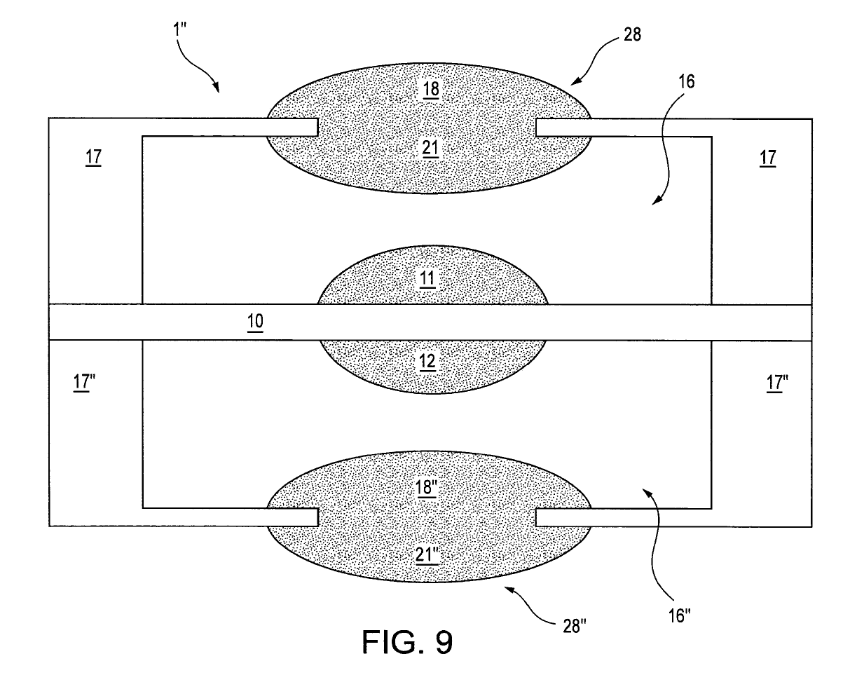

FIG. 9 shows an alternative embodiment where glass substrate 10 has MEMS structures affixed to both sides, thus creating a lens structure 1″ with two movable lens structures 28, 28″. MEMS structures 17 and lens structure 28 are similar to MEMS structures 17, 17′ and lens structures 28, 28′, respectively in FIGS. 1A, 1B and can be constructed according to an appropriate embodiment described herein in FIGS. 2A-8E. Likewise, MEMS structures 17″ and lens structures 28″ are similar to MEMS structures 17, 17′ and lens structures 28, 28′ in FIGS. 1A, 1B and can be constructed according to an appropriate embodiment described herein in FIGS. 2A-8E. As with

FIGS. 1A and 1B, lens structures 28, 28″ can have two lenses as shown in FIG. 9, or one or both of lens structures 28, 28″ can have only one lens. In addition, lenses 11 and 12 are optional such that transparent substrate 10 may have only one lens (11 or 12) attached or may have no lens attached.

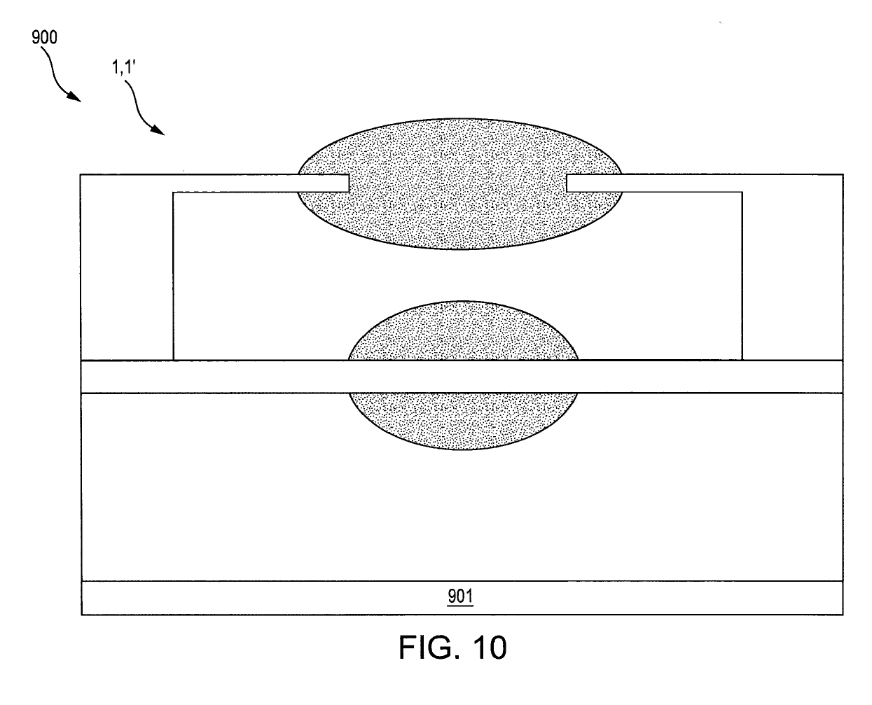

FIG. 10 shows one example of how a lens stack 1, 1′ can be used in an imaging module 900. Imaging module 900 contains a lens stack 1, 1′ according to an embodiment described herein, over an image sensor 901. The lens stack lens stack 1, 1′ is used to focus an image on the image sensor 901.

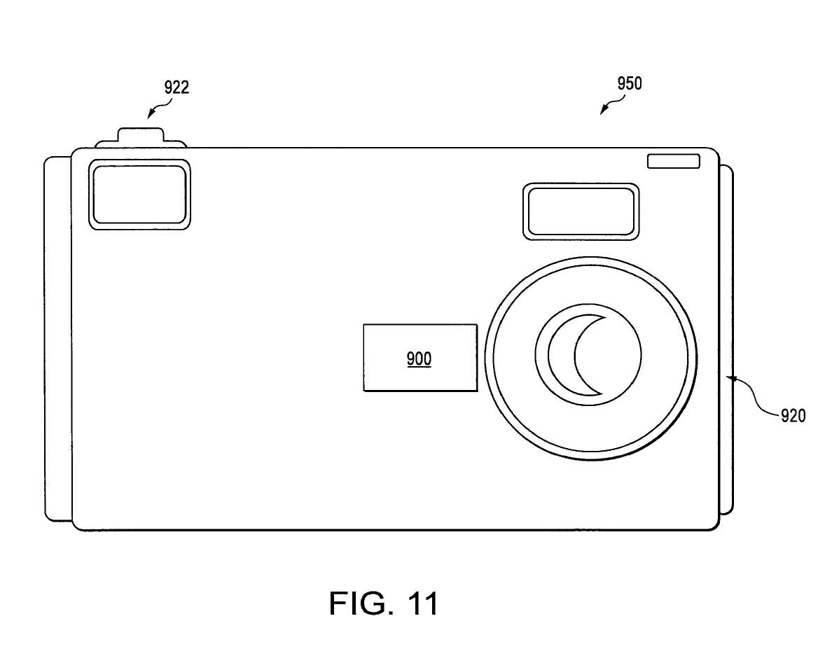

FIG. 11 shows a typical imaging system 950 modified to include an imager 900 constructed and operated in accordance with an embodiment described above. The system 950 is a system having digital circuits that could include imaging devices. Without being limiting, such a system could include a computer system, camera system, scanner, machine vision, vehicle navigation, video telephone, surveillance system, automatic focus system, star tracker system, motion detection system, image stabilization system, or other image acquisition system.

In the system 950, for example a digital still or video camera system, a lens 920 is used to focus light onto an image sensor 901 (FIG. 10) of the imaging device 900 when a shutter release button 922 is pressed.

What is claimed as new and desired to be protected by Letters Patent of the United States is:

1. An imaging module comprising an image sensor and a lens stack, the lens stack comprising:
a transparent substrate;
at least one fixed lens attached to the transparent substrate;
at least one movable structure attached to the transparent substrate; and
at least one movable lens suspended above the transparent substrate by the movable structure.

2. The imaging module of claim 1, wherein the at least one movable lens comprises a flexible material.

3. The imaging module of claim 2, wherein the flexible material comprises polydimethylsiloxane.

4. The imaging module of claim 1, wherein the at least one movable lens comprises a rigid transparent material.

5. The imaging module of claim 4, wherein the rigid transparent material comprises an Ormocer®.

6. The imaging module of claim 1, wherein the at least one movable lens comprises a material having properties that vary along the radius of the at least one movable lens.

7. A digital camera comprising an imaging module, the imaging module comprising an image sensor and a lens stack, the lens stack comprising:
a transparent substrate;
at least one fixed lens attached to the transparent substrate;
at least one movable structure attached to the transparent substrate; and
at least one movable lens suspended above the transparent substrate by the movable structure.

8. The digital camera of claim 7, wherein at least one of the at least one fixed lenses is concave.

9. The digital camera of claim 7, wherein at least one of the at least one fixed lenses is convex.

10. The digital camera of claim 7, wherein at least one of the at least one movable lenses is concave.

11. The digital camera of claim 7, wherein at least one of the at least one movable lenses is convex.

12. A method of manufacturing a lens stack, the method comprising:
attaching at least one movable structure to a transparent substrate; and
forming a movable lens in contact with the at least one movable structure.

13. The method of claim 12, further comprising:
removing a sacrificial material attached to the at least one movable structure to free the at least one movable structure from a fixed position.

14. A method of manufacturing a lens stack, the method comprising:
providing a transparent substrate with at least one fixed lens attached;
affixing a temporary carrier to a first side of the transparent substrate;
providing a silicon substrate having a cavity filled with a sacrificial material;
affixing the silicon substrate to a second side of the transparent substrate;
forming at least one movable structure from the silicon substrate; and
imprinting a first movable lens on the at least one movable structure.

15. The method of claim 14, further comprising:
removing the sacrificial material to allow movement of the at least one movable structure.

16. The method of claim 14, further comprising:
removing the temporary carrier.

17. The method of claim 14, wherein the sacrificial material comprises SiO₂.

18. The method of claim 14, wherein the sacrificial material comprises a polymer.

19. The method of claim 14, wherein the forming of at least one movable structure comprises silicon micromachining the silicon substrate.

20. The method of claim 14, wherein the removing of the sacrificial material comprises dissolving the sacrificial material.

21. The method of claim 14, wherein the removing of the sacrificial material comprises extracting the sacrificial material through at least one hole in the at least one movable structure.

22. A method of manufacturing a lens stack, the method comprising:
providing a silicon carrier having at least one movable structure and a sacrificial layer;
affixing a transparent substrate to the at least one movable structure such that a fixed lens is attached to the transparent substrate between the transparent substrate and the sacrificial layer;
removing the silicon carrier;
forming a movable lens structure on the at least one movable structure; and
removing the sacrificial material.

23. The method of claim 22, wherein the affixing of the transparent substrate comprises:
imprinting a lens-shaped cavity in the sacrificial material;
filling the cavity with lens replication material; and
attaching the lens replication material and the at least one movable structure to the transparent substrate.

24. The method of claim 23, further comprising planarizing the lens replication material.

25. The method of claim 22, wherein the step of affixing the transparent substrate comprises:
affixing the transparent substrate to at least one movable structure;
removing the sacrificial material to reveal a cavity;
imprinting the fixed lens in the cavity and on the transparent substrate; and
filling the cavity with a second sacrificial material.

26. The method of claim 25, wherein the removing the silicon carrier occurs after the affixing the transparent substrate and before the removing the sacrificial material.

27. The method of claim 22, wherein forming the movable lens structure comprises:
imprinting a lens-shaped cavity in the sacrificial layer; and
forming the movable lens structure with a first movable lens in the lens-shaped cavity and a second movable lens over the at least one movable structure.

28. The method of claim 22, further comprising:
forming a second fixed lens on the transparent substrate such that the transparent substrate is between the fixed lens and the second fixed lens.

29. A method of manufacturing a lens stack, the method comprising:
providing a transparent substrate with at least one fixed lens attached;
affixing a temporary carrier to the transparent substrate;
providing a silicon substrate with at least one movable structure attached and a cavity between the at least one movable structure filled with a sacrificial material, wherein a first movable lens is provided in the cavity on the at least one movable structure;
providing a silicon substrate having a cavity filled with a sacrificial material;
affixing the at least one movable structure to the transparent substrate;
removing the silicon substrate; and
imprinting a second movable lens on the at least one movable structure.

30. The method of claim 29, further comprising:
removing the sacrificial material to allow movement of the at least one movable structure.
